(19) United States
(12) Patent Application Publication
(10) Pub. No.: US 2021/0165036 A1
(43) Pub. Date: Jun. 3, 2021

(54) TESTING CABLE FOR VOIP, ISDN, DATA, AND ANALOG COMMUNICATION

(71) Applicant: UNIVERSITY OF SOUTHERN CALIFORNIA, Los Angeles, CA (US)

(72) Inventor: Oscar ARCIGA, Whittier, CA (US)

(21) Appl. No.: 17/106,984

(22) Filed: Nov. 30, 2020

Related U.S. Application Data
(60) Provisional application No. 62/941,914, filed on Nov. 29, 2019.

(51) Int. Cl. G01R 31/28; H01B 11/02; G01R 1/073

(52) U.S. Cl. CPC G01R 31/2825; H01R 24/64; G01R 1/07307; H01B 11/02

(57) ABSTRACT

A test cable is adapted to test punch down blocks used in voice or data communication wiring. The test cable includes a patch cable section having a plurality of wires surrounded by a sheath, a first adapter connected to an end of the patch cable section, a plurality of sub-cables that emerge from patch cable section, each sub-cable including a pair of wires continuing from the plurality of wires in the patch cable section, and a plurality of sub-cable adapters connected to the plurality of sub-cables. Characteristically, each sub-cable has a sub-cable adapted thereto. A method for applying the test cable is also provided.

### CROSS-REFERENCE TO RELATED APPLICATIONS

This application claims the benefit of U.S. provisional application Ser. No. 62/941,914 filed Nov. 29, 2019, the disclosure of which is hereby incorporated in its entirety by reference herein.

### TECHNICAL FIELD

In at least one aspect, a testing cable for communication applications is provided.

### BACKGROUND

Test cables used for evaluating wiring in voice and data communication systems are known. The prior art test cable are adapted to evaluating wiring connections in punch down blocks where related wiring pairs are side by side. Although initially the communications wiring is typically arranged with this side by side arrangement, the development of bad pairs often results in related pair to become split and lose this side by side arrangement. This loss of proximity of adjacent pairing makes

Accordingly, there is a need for improved communication test cables that can be used to test non-adjacent or split wiring pairs in punch down blocks.

### SUMMARY

In at least one aspect, a test cable is adapted to test punch down blocks used in voice or data communication wiring. The test cable includes a patch cable section having a plurality of wires surrounded by a sheath, a first adapter connected to an end of the patch cable section, a plurality of sub-cables that emerge from patch cable section, each sub-cable including a pair of wires continuing from the plurality of wires in the patch cable section, and a plurality of sub-cable adapters connected to the plurality of sub-cables. Characteristically, each sub-cable has one of the plurality of sub-cable adapters attached thereto.

In another aspect, a test cable has the ability to split the pairs on the cable so that a connection to the right pairs on the block can still be made.

In another aspect, for situations where there is a separate 110 power that provides power to the end-user equipment, the test cable provides the ability to connect to the blocks and connect to the power.

In another aspect, a method for testing punch down blocks used in voice or data communication wiring is provided. The method includes a step of providing the test cable set forth herein. The first adapter of the testing cable is attached to a testing device. One or more of the sub-cable adapters are attached to one or more wiring pairs in the punch down block. Measurements are then taken with the testing device.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1. Schematic illustration of a test cable having a plurality of sub-cables emerging from a main cable.

FIG. 2A. Side view of a Krone 1 Pair Test Plug Set.

FIG. 2B. Top view of a Krone 1 Pair Test Plug Set.

FIG. 3. Perspective view of a 1-pair Patch Plug 110C-C-1P.

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

For any device described herein, linear dimensions and angles can be constructed with plus or minus 50 percent of the values indicated rounded to or truncated to two significant figures of the value provided in the examples. In a refinement, linear dimensions and angles can be constructed with plus or minus 30 percent of the values indicated rounded to or truncated to two significant figures of the value provided in the examples. In another refinement, linear dimensions and angles can be constructed with plus or minus 10 percent of the values indicated rounded to or truncated to two significant figures of the value provided in the examples.

The term “computing device” refers generally to any device (e.g., a laptop or desktop computer) that can perform at least one function, including communicating with another computing device.

The term “punch-down block” refers to a type of electrical connection used in telephony. In this connection, the wires (e.g., copper wires) are “punched down” into short open-ended slots (i.e., a type of insulation-displacement connector).

Abbreviations:

“ISDN” means integrated services digital network.

“MPOE” means minimum point of entry.

“PE” means polyethylene.

“VOIP” means voice over internet protocol.

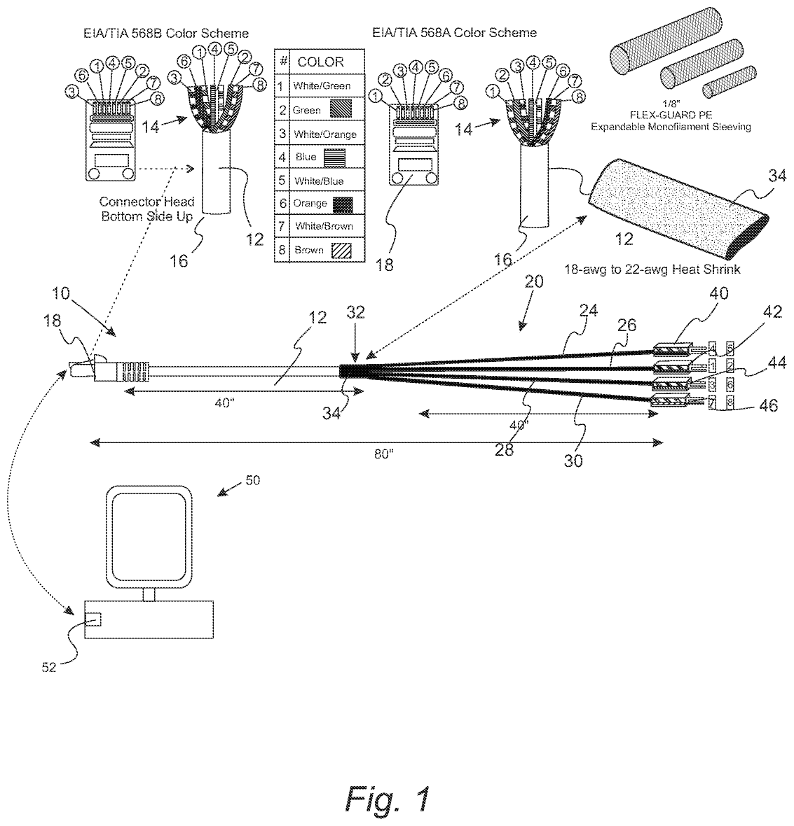

With reference to FIG. 1, a schematic of a test cable for testing of communications (Voice or Data) on communication punch down blocks is provided. Test cable 10 includes a patch cable section 12 that has a plurality of wires 14 surrounded by sheath 16. Typically, the plurality of wires is arranged as a plurality of twisted pairs. In a refinement, the plurality of wires 14 includes 8 wires that are typically color-coded as indicated in FIG. 1. Adapter 18 is attached to a first end of the patch cable section 12. In a refinement, adapter 18 is an 8P8C modular connector using either T568A or T568B pin assignments. Examples of adapter 18 include, but are not limited to, RJ11, RJ14 connectors, RJ25 connectors, RJ45S connectors, RJ49 connectors, RJ61 connectors, and the like. Advantageously, test cable 10 is adapted to test punch down blocks used in communication applications.

Still referring to FIG. 1, test cable 10 also includes a plurality 20 of sub-cables 24, 26, 28, 30 that emerge from patch cable section 12 at location 32. Each sub-cable includes a pair of wires continuing from the plurality of wires 14. In a refinement, each pair of wires is a twisted pair.

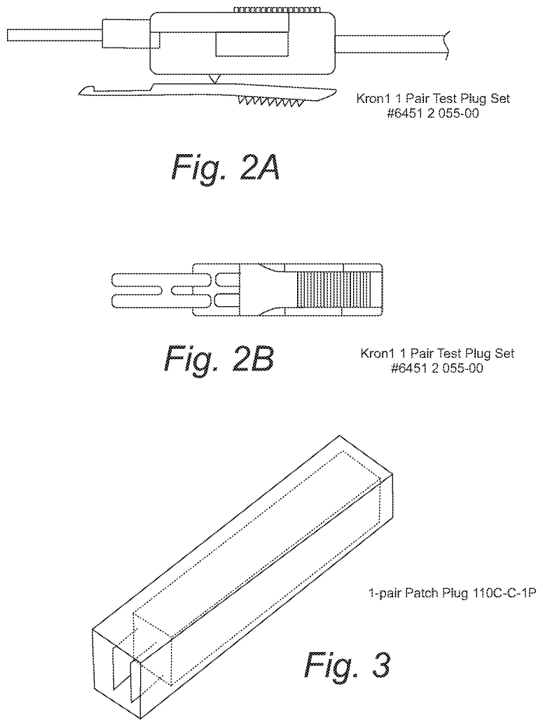

In a further refinement, location 32 is protected by sheath 34. For example, sheath 34 can be formed from a heat-shrinkable sleeve (e.g. expanded monofilament sleeving. Sub-cable adapters 40, 42, 44, 46 are respectively connected to the end of sub-cables 24, 26, 28, 30. Examples for adapters 40, 42, 44, 46 include but are not limited to, Krone 1 Pair Test Plug Set as depicted in FIGS. 2A and 2B and a 1-pair Patch Plug 110C-C-1P as depicted in FIG. 3.

Advantageously, test cable 10 can be used for testing punch down blocks including, but not limited to, Krone Blocks and 110 type Blocks. Testing with test cable 10 can work on different applications by simply changing the type of Test Patch/Plug that is put on the individual pairs located on the opposite side of the RJ45. The main purpose of this cable is to allow telecommunications testing in applications where the pairs on the Punch Block are split (i.e., not adjacent to each other).

In another embodiment, a method for testing punch down blocks used in voice or data communication wiring is provided. The method includes a step of providing the test cable 10 as set forth above with respect to the descriptions related to FIGS. 1 and 2. The first adapter of the testing cable is attached to a testing device. One or more of the sub-cable adapters are attached to one or more wiring pairs in a punch down block. Typically, the punch down block is a component of the phone communication system or of a data communication system. Finally, measurements are then taken with the testing device. In a refinement, at least two of the sub-cable adapters are attached to non-adjacent wiring pairs.

In one variation of the method, the test cable can be used in a phone communication application. Phone communication handoff from providers at the MPOE (e.g., on incoming underground pairs). ISDN, for example, can come in Two pair (already demodulated), and one pair (Modulated Custom or National signal). Two Pair ISDN, or One pair “U” after it goes through demodulation equipment, can be tested at the MPOE, and at every riser point the wiring goes through, even if the cross-connect wires are split For example, if transmit is punched done on the first pair (pair 1), the receive is on the last pair (pair 100), and power is in the middle (pair 50) on a 100 pair block. Test cable 10 allows a user to test the line with nothing more than the phone that will be installed and this cable. Simply plug in first adapter 18 (e.g., an R145 connector) to the ISDN phone, and the individual pairs of sub-cables 24, 26, 28, 30 on the opposite side of test cable 10 are connected to their perspective connection on the block. (e.g., blue is receive, green is transmit, brown is power)

Single line/Analog phones can also be tested following the same idea. A technician can plug in the blue pair to the block, and the RG45 to a harmonica tool which a bud set is typically connected to via pairs 4 and 5. An alternative if someone does not have a harmonica tool and bud set is to use the phone that will be installed as a testing unit by plugging in the RJ45 to the phone. If the phone does not take an RJ45, a coupler and a 4 pair line cord can be used to reduce the pairs and make the connection.

In another variation of the method, data can also be tested with the test cable. In particular, data can also be tested since some refinements of test cable 10 are Cat6A. In some applications, data connection originates in the data switch and is feed to a punch down block that cross-connects to jacks and risers to other floors. Test cable 10 allows the user to connect computing devices 50 (e.g., a laptop) directly by plugging first adapter 18 (e.g., RJ45 connector) into to the Ethernet port 52 of the computing device. The individual pairs of sub-cables 24, 26, 28, 30 on the opposite side of test cable 10 are connected to the switch punch down ports. Data connectivity can by tested at every riser point on the way to the jack even if the riser cross-connects are split because of riser availability (Example for 10 meg is that pairs 1, 2 can be on pair 1 on the block, and 3, 6 can be 92 on the block. For 100, or 1 Gig and higher all 4 pairs are needed. This cable allows testing, even if they are separated by as much as 1 foot from each other.)

Similarly, other data switches provide data via RJ45 port on the face of a switch. The first adapter 18 (e.g., a RJ45 connector) is plugged in with individual pairs of sub-cables 24, 26, 28, 30 on the opposite side of test cable 10 being punched down to a jack number, or riser pairs (it is punched down to a riser pair if sub closets are needed to reach other parts of the building or if a building is two stories or more and each floor has a telecom closet). At that point, the test cable allows a user to connect a laptop directly by plugging in the first adapter 18 (e.g., RJ45 to the Ethernet port), and the individual pairs on the opposite side of the cable to the risers/punch block. Data connectivity can be tested at every riser point on the way to the jack even if the riser cross-connects are split because of riser availability. (Example for 10 meg is that pairs 1, 2 can be on pair 1 on the block, and 3, 6 can be 92 on the block. For 100, or 1 Gig and higher all 4 pairs are needed. This cable allows testing, even if they are separated by as much as 1 foot from each other.)

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A test cable adapted to test punch down blocks used in voice or data communication wiring, the test cable comprising:
a patch cable section having a plurality of wires surrounded by a first sheath;
a first adapter connected to an end of the patch cable section;
a plurality of sub-cables that emerge from patch cable section, each sub-cable including a pair of wires continuing from the plurality of wires in the patch cable section; and
a plurality of sub-cable adapters connected to the plurality of sub-cables wherein each sub-cable has one of the plurality of sub-cable adapters attached thereto, the test cable adapted to test punch down blocks.

2. The test cable of claim 1 wherein the first adapter is a P8C modular connector using either T568A or T568B pin assignments.

3. The test cable of claim 1 wherein the plurality of wires are arranged as a plurality of twisted pairs.

4. The test cable of claim 3 wherein pair of wires continuing from the plurality of wires in the patch cable section is a twisted pair.

5. The test cable of claim 1 wherein the plurality of wires is color coded.

6. The test cable of claim 1 wherein a second sheath is positioned over the test cable at a location where the plurality of sub-cables that emerge from the patch cable section.

7. A method for testing punch down blocks used in voice or data communication wiring, the method comprising:
a) providing a test cable comprising:
a patch cable section having a plurality of wires surrounded by a sheath;
a first adapter connected to an end of the patch cable section;
a plurality of sub-cables that emerge from patch cable section, each sub-cable including a pair of wires continuing from the plurality of wires in the patch cable section; and
a plurality of sub-cable adapters connected to the plurality of sub-cables wherein each sub-cable has one of the plurality of sub-cable adapters attached thereto, the test cable adapted to test punch down blocks;
b) attaching the first adapter to a testing device; and
c) attaching one or more of the sub-cable adapters to one or more wiring pairs in a punch down block.

8. The method of claim 7 further comprising taking measurements with the testing device.

9. The method of claim 7 wherein two of the sub-cable adapters are attached to non-adjacent wiring pairs.

10. The method of claim 7 wherein the testing device is an ISDN phone.

11. The method of claim 7 wherein the testing device is a computing device.

12. The method of claim 7 wherein the testing device is a harmonica tool.

13. The method of claim 7 wherein the punch down block is a component of a phone communication system.

14. The method of claim 7 wherein the punch down block is a component of a data communication system.

15. The method of claim 7 wherein the first adapter is a P8C modular connector using either T568A or T568B pin assignments.

16. The method of claim 7 wherein the plurality of wires are arranged as a plurality of twisted pairs.

17. The method of claim 7 wherein the plurality of wires are color-coded.
